(19) United States
(12) Patent Application Publication
(10) Pub. No.: US 2012/0025336 A1
(43) Pub. Date: Feb. 2, 2012

(54) CONVERTER MODULE AND METHOD OF MANUFACTURING THE SAME

(75) Inventors: Daisuke INOUE, Osaka (JP); Kyoko FUJII, Osaka (JP)

(73) Assignee: PANASONIC CORPORATION, Osaka (JP)

(21) Appl. No.: 13/268,373

(22) Filed: Oct. 7, 2011

Related U.S. Application Data
(63) Continuation of application No. PCT/JP2010/001034, filed on Feb. 18, 2010.

(30) Foreign Application Priority Data
Apr. 14, 2009 (JP) 2009-098482

(51) Int. Cl. H01L 29/80; H01L 21/02

(52) U.S. Cl. 257/416; 257/419; 438/53; 257/E29.324; 257/E21.002

(57) ABSTRACT

To provide a converter module easily achieving miniaturization and profile reduction without decreasing the pressure detection sensitivity. The converter module includes: a converter which converts vibration of a diaphragm into an electric signal; and a semiconductor substrate which processes the electric signal obtained as a result of the conversion performed by the converter. The converter includes: a base including a cavity part having an opening in a front surface of the base; and the diaphragm which is arranged on the front surface to cover the opening of the cavity part and converts the vibration into the electric signal. The semiconductor substrate is formed as a part of the base.

### CROSS REFERENCE TO RELATED APPLICATION

This is a continuation application of PCT application No. PCT/JP2010/001034 filed on Feb. 18, 2010, designating the United States of America.

### BACKGROUND OF THE INVENTION

(1) Field of the Invention

The present invention relates to a converter module including a converter, such as a sound pressure sensor or a pressure sensor, and to a method of manufacturing the converter module.

(2) Description of the Related Art

Conventionally, a converter module including a converter, such as a silicon microphone or a pressure sensor, detect pressure fluctuations of, for example, sound by sensing vibration of a diaphragm included in a sound pressure sensor chip or a pressure sensor chip, as disclosed in Japanese Unexamined Patent Application Publication Nos. 2004-537182 and 2007-263677. Hereafter, these references are referred to as Patent Reference 1 and Patent Reference 2, respectively.

FIG. 21 is a cross-sectional diagram of a conventional converter module 500 disclosed in Patent Reference 1. As shown, in the conventional converter module 500, a converter 501 and a semiconductor substrate 503 are implemented on a main surface of a circuit substrate 504. The converter 501 has a diaphragm 502, and the semiconductor substrate 503 controls the converter 501. Moreover, a cavity part 507 is formed in the circuit substrate 504, immediately below the diaphragm 502. The converter 501 and the semiconductor substrate 503 are covered with a shielding cap 505. With this arrangement, the diaphragm 502 vibrates in response to a sound wave transmitted via a sound hole 506 penetrating the shielding cap 505. Then, the converter module 500 detects the pressure fluctuations of the sound wave from the vibration of the diaphragm 502.

Here, when the cavity part 507 is small in volume, the air resistance of the cavity part 507 is large, which makes it hard for the diaphragm to vibrate. As a result, the amount of displacement of the diaphragm 502 is small, meaning that the pressure fluctuations cannot be detected with accuracy.

On this account, in order for the diaphragm 502 to vibrate, it is necessary for the cavity part 507 to have an adequate volume. Moreover, the volume of the cavity part 507 needs to be changed as appropriate according to the characteristics of the converter 501.

In the case of the conventional converter module 500, the cavity part 507 is formed to be recessed from the main surface of the circuit substrate 504 so that the volume of the cavity part 507 is increased. However, since the converter 501 and the semiconductor substrate 503 are arranged side by side on the circuit substrate 504, the circuit substrate 504 is large in area size, which leads to a problem that it is difficult to downsize the converter module 500.

To address this problem, Patent Reference 2 discloses a converter module in which a semiconductor substrate, a converter, a shielding cap are laminated on a circuit substrate. In this disclosed example, a cavity part is formed to be recessed from a main surface of the semiconductor substrate so that the volume of the cavity part located immediately below a diaphragm is not decreased.

### SUMMARY OF THE INVENTION

In the conventional converter module having the laminated structure as disclosed in Patent Reference 2, the circuit substrate, the semiconductor substrate, the converter, and the shielding cap are laminated in order from bottom to top. Therefore, the converter module is thick, and a reduction in profile of the converter module is difficult.

Examples of the method to reduce the profile of the converter module having the above configuration include (1) thinning the converter and (2) thinning the semiconductor substrate. However, the method (1) causes concern that the strength of the converter is compromised due to the thinned converter. The method (2) also causes concern that the pressure fluctuations cannot be detected with accuracy because it is hard for the diaphragm to vibrate due to the reduced volume of the cavity part.

Moreover, the conventional configuration has another problem with the detection sensitivity of the converter module. The detection sensitivity of the converter module can be expressed quantitatively by Equation 1 below, where “Sen” represents the detection sensitivity.

$$Sen = \frac{ES}{d} {C}_{ges} \frac{1}{1 + {ω}^{2} {M}_{0} {C}_{ges} - jω {r}_{0} {C}_{ges}} \qquad Equation 1$$

Here, “C_{ges}” is expressed by Equation 2 below.

$${C}_{ges} = {( \frac{1}{{C}_{m}} + \frac{1}{{C}_{v}} )}^{- 1} \qquad Equation 2$$

In Equation 1 above: “E” represents an electric field; “S” represents an area size of the diaphragm; “d” represents a distance between two pairs of diaphragms; “C_{ges}” represents combined compliance; “Cₘ” represents compliance of the diaphragm; “Cᵥ” represents compliance of the cavity part; “M₀” represents a mass of the diaphragm; and “r₀” represents a radiation impedance. When a resonant frequency of the diaphragm is adequately low, Equation 1 is chanced into Equation 3 as follows.

$$Sen = \frac{ES}{d} {C}_{ges} = \frac{ES}{d} {( \frac{1}{{C}_{m}} + \frac{1}{{C}_{v}} )}^{- 1} \qquad Equation 3$$

The compliance Cₘ of the diaphragm is expressed by Equation 4 below.

$${C}_{m} = \frac{1}{k} \qquad Equation 4$$

In Equation 4, “k” represents a spring constant of the diaphragm.

The compliance Cᵥ of the cavity part is expressed by Equation 5 below.

$${C}_{v} = \frac{V}{{S}^{2} γ {P}_{0}} \qquad Equation 5$$

In Equation 5, “V” represents a volume of the cavity part, “y” represents a specific heat resistance of air, and “P₀” represents a normal atmospheric pressure.

As can be understood from Equation 4, Cₘ increases as the diaphragm becomes softer. Moreover, as can be understood from Equation 5, Cᵥ increases as the volume of the cavity part is increased.

By increasing each value of the parameters in Equation 3, the detection sensitivity Sen can be improved. To be more specific, one of the values of the electric field E, the area size S, the diaphragm compliance Cₘ, and the cavity compliance Cᵥ may be increased. Alternatively, the distance d between the diaphragms may be reduced.

However, there is a limit to use the electric field E, and there is also a limit to the distance d between the two pairs of diaphragms in the manufacturing process. Thus, in order to improve the detection sensitivity, it is necessary to (A) increase the area size S of the diaphragm or (B) increase the cavity compliance Cᵥ by increasing the cavity volume V.

In the case of (A), however, the converter needs to be increased in size so as to increase the area size S of the diaphragm. When the area size of the diaphragm is increased, this means that the detection sensitivity decreases because the cavity compliance decreases as can be understood from Equation 5. In order to address this, the recessed part of the semiconductor substrate needs to be increased in size so as to increase the area size of the diaphragm, and the volume of the cavity part also needs to be increased.

In the case of (B), the recessed part needs to be increased in size by increasing the size of the semiconductor substrate, as is the case with (A). That is to say, as the detection sensitivity of the converter is increased, the size of the semiconductor substrate is accordingly increased. On this account, when a converter module is designed, the size of a semiconductor substrate is determined according to the detection sensitivity of a converter.

The present invention is conceived in view of the aforementioned conventional problem, and has an object to provide a converter module and a method of manufacturing the same capable of easily achieving miniaturization and profile reduction without decreasing the pressure detection sensitivity.

In order to achieve the above object, the converter module according to an aspect of the present invention is a converter module including: a converter which converts vibration of a diaphragm into an electric signal; and a semiconductor substrate which processes the electric signal obtained as a result of the conversion performed by the converter, wherein the converter includes: a base including a cavity part having an opening in a first main surface of the base; and the diaphragm which is arranged on the first main surface to cover the opening of the cavity part and converts the vibration into the electric signal, and the semiconductor substrate is formed as a part of the base.

With this configuration, since the semiconductor substrate is formed as a part of the base in which the cavity part is formed, the volume of the cavity part can be adequately ensured without having to increase the converter module in thickness. Thus, the pressure detection sensitivity does not decrease. As compared with the configuration where a semiconductor substrate and a converter are arranged side by side or are laminated, the converter module can be miniaturized and reduced in profile more easily.

Moreover, a part of a side surface of the semiconductor substrate may face the cavity part.

With this, the cavity part can be increased in volume and, therefore, the accuracy of the pressure detection can be improved more.

Furthermore, a part of a side surface of the base and a part of a side surface of the semiconductor substrate may be in one plane.

With this, the converter modules can be easily diced from an array in which a plurality of converters are formed. This allows the converter module to be manufactured at lower cost.

Moreover, the base may include a recessed part having an opening in a second main surface of the base, the second main surface being opposite to the first main surface, and the semiconductor substrate may be formed in the recessed part.

With this, the diaphragm can be supported precisely, and the strength of the converter can also be maintained. Thus, the accuracy of the pressure detection can be improved.

Furthermore, the base may include a through area penetrating from the first main surface to a second main surface opposite to the first main surface, and the semiconductor substrate may be formed in the through area.

With this, the cavity part and the through area can be formed at one time. This can simplify the manufacturing process and, thus, the converter module can be manufactured at low cost. Moreover, since the electrode part connecting the diaphragm and the semiconductor substrate can be shortened, parasitic resistance caused by the electrode part can be reduced.

Moreover, the second main surface of the base and a main surface of the semiconductor substrate may be in one plane.

With this, even when the semiconductor substrate is formed as a part of the base, the thickness of the base does not change and thus the converter module can be reduced in profile.

Furthermore, the converter module may further include: a first insulating layer formed between the semiconductor substrate and the base; and a first penetrating electrode penetrating each of the base and the first insulating layer in a thickness direction and electrically connecting the diaphragm and the semiconductor substrate.

With this, current is prevented from leaking from the first penetrating electrode.

Moreover, the converter module may further include a protection layer including a hole penetrating in a thickness direction, wherein the protection layer is arranged above the diaphragm so that the opening of the cavity part is located immediately below the hole.

With this, since the hole is formed immediately above the diaphragm, air flow such as a sound wave can be controlled to head for the diaphragm. As a result, the diaphragm can vibrate with accuracy.

Furthermore, the protection layer may include electrical wiring for transmitting, to an external source, the electric signal processed by the semiconductor substrate, and the converter module may further include a second penetrating electrode penetrating the base in a thickness direction and electrically connecting the semiconductor substrate and the electrical wiring.

With this, the electric signal processed by the semiconductor substrate can be easily extracted outside.

Moreover, the converter module may further include: a second insulating layer formed between the first main surface of the base or the diaphragm and the protection layer; and an external electrode penetrating the second insulating layer and electrically connecting the second penetrating electrode and the electrical wiring.

With this, current is prevented from leaking from the second penetrating electrode.

Furthermore, the converter module may further include a shielding cap protecting a second main surface of the base and a side surface of the base, the second main surface being opposite to the first main surface.

With this, the converter module can be protected from an external shock or from noise caused by an electromagnetic wave or the like.

Moreover, the converter module may further include: a circuit substrate which includes electrical wiring for transmitting, to an external source, the electric signal processed by the semiconductor substrate and is formed on a second main surface of the base, the second main surface being opposite to the first main surface; and a third penetrating electrode penetrating the semiconductor substrate in a thickness direction and electrically connecting the semiconductor substrate and the electrical wiring.

With this, since the hole is formed immediately above the diaphragm, air flow such as a sound wave can be controlled to head for the diaphragm. As a result, the diaphragm can vibrate with accuracy. Moreover, the electric signal processed by the semiconductor substrate can be easily extracted outside.

Furthermore, the protection layer may be a shielding cap further protecting the base by covering a side surface of the base.

With this, the converter module can be protected from an external shock or from noise caused by an electromagnetic wave or the like.

Moreover, the method of manufacturing the converter module according to another aspect of the present invention is a method of manufacturing a converter module including a converter which converts vibration of a diaphragm into an electric signal and a semiconductor substrate which processes the electric signal obtained as a result of the conversion performed by the converter, the converter including: a base; and the diaphragm which is arranged on a first main surface of the base and converts the vibration into the electric signal, and the method including: etching the base from a second main surface opposite to the first main surface to form a cavity part in an first area immediately below the diaphragm and a recessed part in a second area different from the first area, the cavity part penetrating the base in a thickness direction; and bonding the semiconductor substrate to the recessed part formed in the etching.

With this configuration, since the semiconductor substrate is formed as a part of the base, the volume of the cavity part can be adequately ensured without having to increase the converter module in thickness. Thus, the pressure detection sensitivity does not decrease. As compared with the configuration where a semiconductor substrate and a converter are arranged side by side or are laminated, the converter module can be miniaturized and reduced in profile more easily.

Furthermore, in the etching, the cavity part and the recessed part may be formed in each of a plurality of converters formed in an array so that the formed recessed parts of two adjacent converters are adjacent to each other, each of the converters including the base and the diaphragm, in the bonding, two semiconductor substrates may be respectively bonded, at one time, to the adjacent recessed parts formed in the etching, and the method may further include dicing the array so that the plurality of converters are individually separated.

With this, the converter modules can be easily diced from an array in which a plurality of converters are formed. This allows the converter module to be manufactured at lower cost.

Moreover, the etching may include: performing a first etching on the first area immediately below the diaphragm by etching from the second main surface of the base; and performing a second etching on the first area etched in the performing a first etching and on the second area at one time by etching from the second main surface of the base, to form the cavity part in the first area and the recessed part in the second area.

Furthermore, in the performing a first etching, the first area may be etched so that the base immediately below the diaphragm is at least as thick as the semiconductor substrate, and in the performing a second etching, the first area etched in the performing a first etching and the second area may be etched at least as deep as a thickness of the semiconductor substrate.

Moreover, in the etching, the cavity part and the recessed part may be formed at one time so that the recessed part penetrates the base in the thickness direction.

With this, the cavity part and the recessed part can be formed at one time. This can simplify the manufacturing process and, thus, the converter module can be manufactured at low cost.

The converter module according to the present invention can achieve miniaturization and reduction in profile more easily without decreasing the pressure detection sensitivity, as compared with the conventional converter module.

### FURTHER INFORMATION ABOUT TECHNICAL BACKGROUND TO THIS APPLICATION

The disclosure of Japanese Patent Application No. 2009-098482 filed on Apr. 14, 2009 including specification, drawings and claims is incorporated herein by reference in its entirety.

The disclosure of PCT application No. PCT/JP2010/001034 filed on Feb. 18, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a perspective view of a converter module in a first embodiment according to the present invention;

FIG. 2 is a plan view of the converter module in the first embodiment;

FIG. 3 is a cross-sectional view of the converter module in the first embodiment taken along a line A-A in FIG. 2;

FIG. 4 is a cross-sectional view of a configuration of a converter module in a modification of the first embodiment;

FIG. 5 is a cross-sectional view showing a manufacturing process of the converter module in the first embodiment;

FIG. 6 is a cross-sectional view showing a process of bonding a semiconductor substrate in the manufacturing process of the converter module in the first embodiment;

FIG. 7 is a cross-sectional view showing a dicing process in the manufacturing process of the converter module in the first embodiment;

FIG. 8 is a cross-sectional view showing another manufacturing process of the converter module in the first embodiment;

FIG. 9 is a perspective view of a converter module in a second embodiment according to the present invention;

FIG. 10 is a plan view of the converter module in the second embodiment;

FIG. 11 is a cross-sectional view of the converter module in the second embodiment taken along a line B-B in FIG. 10;

FIG. 12 is a cross-sectional view of a configuration of a converter module in a modification of the second embodiment;

FIG. 13 is a perspective view of a converter module in a third embodiment according to the present invention;

FIG. 14 is a plan view of the converter module in the third embodiment;

FIG. 15 is a cross-sectional view of the converter module in the third embodiment taken along a line C-C in FIG. 14;

FIG. 16 is a cross-sectional view of a configuration of a converter module in a modification of the third embodiment;

FIG. 17 is a perspective view of a converter module in a fourth embodiment according to the present invention;

FIG. 18 is a plan view of the converter module in the fourth embodiment;

FIG. 19 is a cross-sectional view of the converter module in the fourth embodiment taken along a line D-D in FIG. 18;

FIG. 20 is a cross-sectional view of a configuration of a converter module in a modification of the fourth embodiment; and

FIG. 21 is a cross-sectional view of a configuration of a conventional converter module.

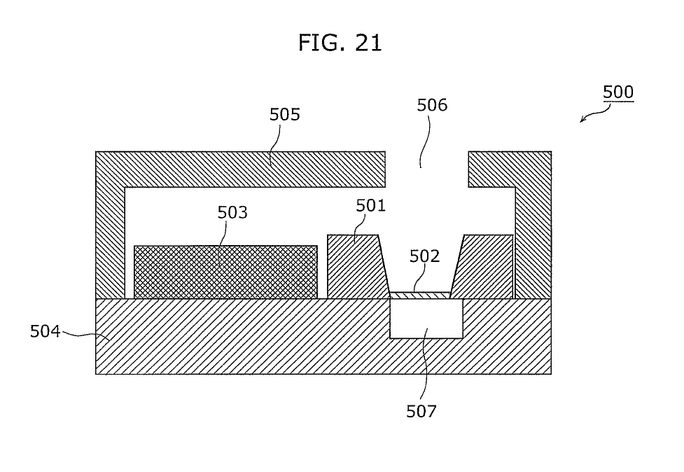

### DESCRIPTION OF THE PREFERRED EMBODIMENTS

The following is a detailed description of embodiments according to the present invention, with reference to the drawings.

### First Embodiment

A converter module in the first embodiment includes a converter and a semiconductor substrate. The converter includes a diaphragm and a base, and converts vibration of the diaphragm into an electric signal. The semiconductor substrate processes the electric signal obtained as a result of the conversion performed by the converter, and is formed as a part of the base.

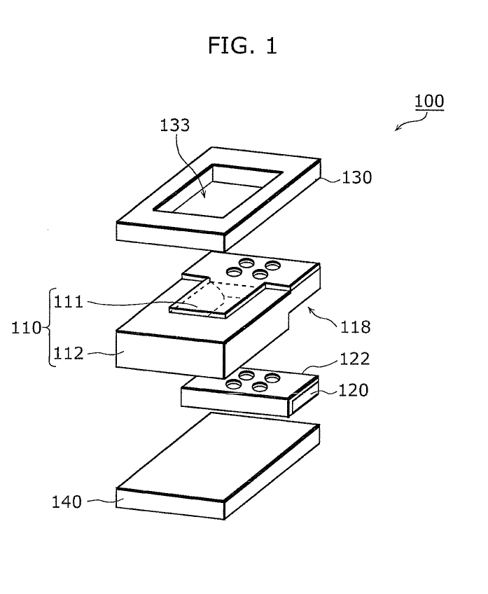

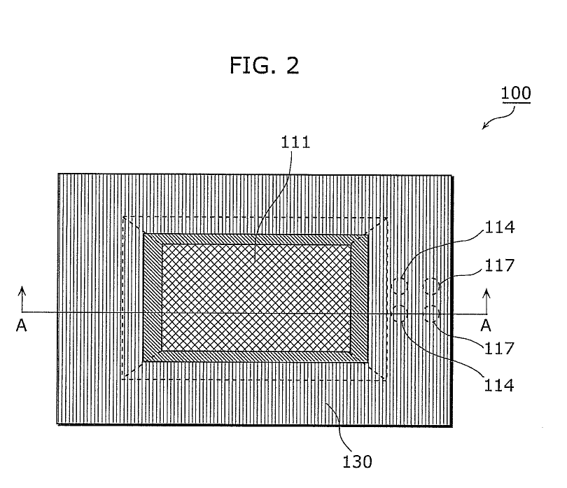

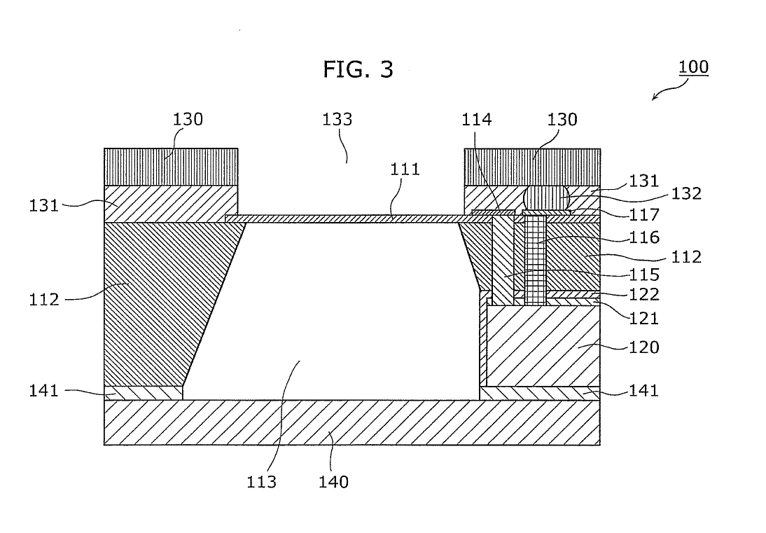

An example of the converter module in the first embodiment is described. FIG. 1 is a perspective view of a converter module 100 in the first embodiment. FIG. 2 is a plan view of the converter module 100 in the first embodiment. FIG. 3 is a cross-sectional view of the converter module 100 in the first embodiment taken along a line A-A in FIG. 2.

As shown in FIG. 1, the converter module 100 includes a converter 110, a semiconductor substrate 120, a circuit substrate 130, and a shielding cap 140. FIG. 2 is a plan view of the converter module 100 shown in FIG. 1, as viewed from above.

The converter 110 includes a diaphragm 111 and a base 112, and converts vibration of the diaphragm 111 into an electric signal.

The diaphragm 111 is formed on a front surface which is a first main surface of the base 112, i.e., an upper surface of the base 112 shown in FIG. 1, to cover an opening of a cavity part 113. The diaphragm 111 vibrates in response to a sound wave or the like and converts the vibration into an electric signal. For example, the diaphragm 111 is a filmy diaphragm of capacitor type having two parallel flat-plate electrodes. In this case, a distance between the parallel flat-plate electrodes changes as a result of the vibration and, thus, electrostatic capacitance varies according to the change in distance. Then, the diaphragm 111 outputs the variations in electrostatic capacitance as the electric signal. It should be noted that the diaphragm 111 is made of, for example, one of or both polysilicon (Poly-Si) and silicon nitride (SiN).

As shown in FIG. 3, the base 112 supports the diaphragm 111 formed on the first main surface of the base 112, and the cavity part 113 having the opening in the front surface of the base 112 is formed immediately below the diaphragm 111. Moreover, as shown in FIG. 1, the base 112 includes a recessed part 118 having an opening in a back surface which is a second main surface of the base 112, i.e., a lower surface opposite to the front surface of the base 112. The semiconductor substrate 120 is formed in this recessed part 118. On the front surface of the base 112, an electrode area 114 and an electrode area 117 are formed as well.

Moreover, the base 112 includes a penetrating electrode 115 for electrically connecting the electrode area 114 and the semiconductor substrate 120. The base 112 also includes a penetrating electrode 116 for electrically connecting the electrode area 117 and the semiconductor substrate 120. The electrode area 117 is used for sending, to an external source, the electric signal received from the semiconductor substrate 120. Here, as shown in FIG. 3, a pair of penetrating electrodes 115 and a pair of penetrating electrodes 116 are formed on the base 112, so that each of the electric signals respectively from the two parallel flat-plate electrodes of the diaphragm 111 is transmitted to the semiconductor substrate 120.

It should be noted that the base 112 is made of, for example, bulk silicon (bulk Si). The thickness of the base 112 shown in the left side of FIG. 3 is approximately 100 μm to 200 μm, and the thickness of the base 112 having the recessed part 118 as shown in the right side of FIG. 3 is approximately 50 μm to 100 μm.

In the case where, for example, the converter module does not need to be reduced in profile, the thickness of the base 112 may be 200 μm or more, like 500 μm. When the base 112 is thicker, the volume of the cavity part 113 can be increased and the strength of the converter module 100 can also be increased, which is preferable. Moreover, in such a case, a polishing process to thin the base 112 can be omitted, which allows the converter module 100 to be manufactured at low cost.

The cavity part 113 is formed immediately below the diaphragm 111 and has the opening in the front surface of the base 112. It is preferable for the volume of the cavity part 113 to be large in order for the diaphragm 111 to fully vibrate. Although FIG. 3 shows that side surfaces of the cavity part 113 are sloped, the cavity part 113 is not limited to the shape shown in FIG. 3 and can be in any shape. For example, the cavity part 113 may have vertical side surfaces and thus be in the shape of a rectangular parallelepiped.

The electrode area 114 is an electrode for extracting the electrical signal from the diaphragm 111. The electrode area 114 electrically connects one of the parallel flat-plate electrodes of the diaphragm 111 and the semiconductor substrate 120, via the penetrating electrode 115. The electrode area 114 is made of a metal, such as Poly-Si or aluminum (Al).

The penetrating electrode 115 is an example of a first penetrating electrode which electrically connects the diaphragm 111 and the semiconductor substrate 120 and penetrates the base 112 in the thickness direction. To be more specific, the penetrating electrode 115 is a conductive region for electrically connecting the electrode area 114 and the semiconductor substrate 120, and fills the inside of a through hole formed in the base 112. The penetrating electrode 115 is made of a metal, such as Poly-Si, Al, titanium (Ti), or copper (Cu).

The penetrating electrode 116 is an example of a second penetrating electrode which electrically connects the semiconductor substrate 120 and electrical wiring formed on the circuit substrate 130 and penetrates the base 112 in the thickness direction. To be more specific, the penetrating electrode 116 is a conductive region for electrically connecting the semiconductor substrate 120 and the electrode area 117, and fills the inside of a through hole formed in the base 112. The penetrating electrode 116 is made of a metal, such as Poly-Si, Al, Ti, or Cu.

The electrode area 117 is an electrode connected to an external electrode 132 so as to send, to the external source, the electric signal processed by the semiconductor substrate 120. The electrode area 117 electrically connects the penetrating electrode 116 and the external electrode 132. The electrode area 117 is made of a metal, such as Poly-Si, Al, Ti, or Cu.

In FIG. 3, the penetrating electrode 115 fills the inside of the through hole. However, the penetrating electrode 115 may be formed only on the inside wall of the through hole so long as the penetrating electrode 115 electrically connects the electrode area 114 and the semiconductor substrate 120. The same holds for the penetrating electrode 116.

The semiconductor substrate 120 processes the electric signal obtained as a result of the conversion performed by the converter 110, and is formed as a part of the base 112. More specifically, as a part of the base 112, the semiconductor substrate 120 supports the diaphragm 111 as well as forming the cavity part 113.

For example, the semiconductor substrate 120, which controls the converter 110, receives the electric signal obtained from the conversion performed by the diaphragm 111 and includes an amplifier circuit for amplifying the received electric signal. The electric signal amplified by the semiconductor substrate 120 is sent to an external source via the external electrode 132. Moreover, the semiconductor substrate 120 is formed in the recessed part 118 of the base 112, as shown in FIG. 1 and FIG. 3.

Furthermore, a part of a side surface of the semiconductor substrate 120 faces the cavity part 113. That is to say, the cavity part 113 is formed by the inner walls of the base 112, the part of the side surface of the semiconductor substrate 120, and the shielding cap 140. In addition, a part of an outer side surface of the base 112 and a part of a side surface of the semiconductor substrate 120 are in one plane.

It is preferable that the back surface of the base 112 and a back surface of the semiconductor substrate 120 are in one plane. To be more specific, it is preferable for the thickness of the base 112 shown in the left side of FIG. 3 to be approximately equal to a sum of the thickness of the base 112 having the recessed part 118 as shown in the right side of FIG. 3 and the thickness of the semiconductor substrate 120.

An insulating film 121 is formed on a front surface of the semiconductor substrate 120. With this, current is prevented from leaking from the penetrating electrode 115. The insulating film 121 is made of oxide silicon (SiO₂) or SiN, for example.

An insulating paste 122 is formed on the insulating film 121. The insulating paste 122 is made of, for example, an insulating resin, and bonds the semiconductor substrate 120 and the base 112 (i.e., the converter 110). When the converter 110 and the semiconductor substrate 120 are bonded, it is preferable not only to bond a main surface of the semiconductor substrate 120 and an exposed back surface of the base 112 where the recessed part 118 is formed, but also to bond the side surface of the semiconductor substrate 120 and the side surface of the base 112 for a stronger bonding as shown in FIG. 1 and FIG. 3.

In this way, the converter module 100 includes a first insulating layer formed between the semiconductor substrate 120 and the base 112. In FIG. 1 and FIG. 3, the first insulating layer corresponds to the insulating film 121 and the insulating paste 122. Note that each of the penetrating electrodes 115 and 116 penetrates both the insulating film 121 and the insulating paste 122 in their thickness directions, as shown in FIG. 3.

The circuit substrate 130 is formed on the converter 110 via an insulating sheet 131. Here, electrical wiring (not illustrated) for an external electric connection may be included in the circuit substrate 130 or may be formed on a front surface of the circuit substrate 130. More specifically, this electrical wiring is used for sending, to an external source, the electrical signal processed by the semiconductor substrate 120. The circuit substrate 130 also functions as a protective layer to protect the upper surface of the converter 110.

The insulating sheet 131 is an example of a second insulating layer formed between the front surface of the base 112 or the diaphragm 111 and the circuit substrate 130. The insulating sheet 131 is made of, for example, an insulating resin, and bonds the circuit substrate 130 and the converter 110.

The external electrode 132 is formed in the insulating sheet 131. The external electrode 132 penetrates the insulating sheet 131, and electrically connects the penetrating electrode 116 and the electrical wiring included in the circuit substrate 130. The external electrode 132 sends, to the circuit substrate 130, the electric signal received from the semiconductor substrate 120 via the penetrating electrode 116. For example, the external electrode 132 is made of a lead-free solder material, which is an alloy of tin (Sn), silver (Ag), and Cu (namely, a Sn—Ag—Cu alloy).

Here, a sound hole 133 is formed in the circuit substrate 130 and the insulating sheet 131. The sound hole 133 penetrates both the circuit substrate 130 and the insulating sheet 131 in their thickness directions. The diaphragm 111 is located immediately below the sound hole 133. In other words, the circuit substrate 130 is located above the diaphragm 111 so that the opening of the cavity part 113 is located immediately below the sound hole 133. The diaphragm 111 vibrates in response to a sound wave transmitted via the sound hole 133. The converter module 100 in the first embodiment can detect pressure fluctuations in the sound wave by sensing the vibration of the diaphragm 111.

The shielding cap 140 is formed under the converter 110 to protect the converter 110 from an external shock or from noise caused by an electromagnetic wave or the like. The shielding cap 140 is boned to the back surface of the base 112 and to the back surface of the semiconductor substrate 120, via a bonding adhesive 141.

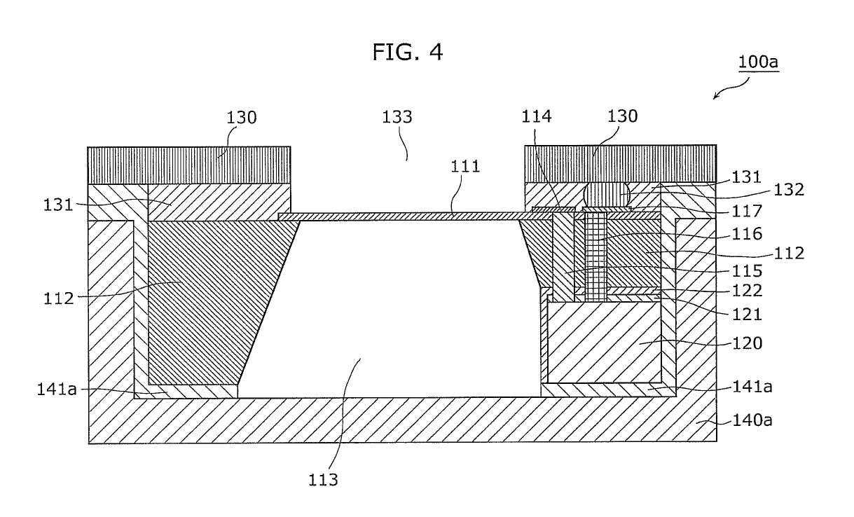

Note that the shielding cap 140 may cover not only a back surface of the converter module 100 but also side surfaces of the converter module 100. FIG. 4 is a cross-sectional view of a configuration of a converter module 100a, as a modification of the converter module 100 in the first embodiment. As shown in FIG. 4, a shielding cap 140a of the converter module 100a covers side surfaces of the converter 110 and the semiconductor substrate 120 as well, via a bonding adhesive 141a. In this way, the shielding cap 140a protects the back surface and side surfaces of the base 112.

With this configuration, the converter module 100a can be more protected from an external shock or from noise caused by an electromagnetic wave or the like. Moreover, in the case where the shielding cap 140a is made of a metal, heat generated by the converter module 100a and the semiconductor substrate 120 can be significantly drawn away. This can reduce warpage and thermal noise which may be caused to the converter module 100a and the semiconductor substrate 120 by the generated heat, thereby improving the accuracy in detecting the vibration of the diaphragm 111. Here, the way of applying the bonding adhesive 141a can be selected as appropriate. More specifically, the bonding adhesive 141a may be fully applied to a surface where the converter 110 and the shielding cap 140a meet or may be applied only to a surface where the circuit substrate 130 and the shielding cap 140a meet.

As described, since the semiconductor substrate 120 is formed in the recessed part 118 of the base 112, the circuit substrate 130 can be equal in area size to the converter 110. Thus, as compared with the conventional configuration where the converter 110 and the semiconductor substrate 120 are arranged side by side on the circuit substrate 130, the converter module 100 can be miniaturized.

In addition, the thickness of the converter 110 (i.e., the base 112) shown in the left side of FIG. 3 can be approximately equal to a sum of the thickness of the converter 110 (i.e., the base 112) shown in the right side of FIG. 3 and the thickness of the semiconductor substrate 120. Thus, as compared with the conventional configuration where the converter 110 is layered on the semiconductor substrate 120, the converter module 100 can be reduced in profile. Here, the thickness of the converter module 100 depends on the sum of the thicknesses of the shielding cap 140, the converter 110, and the circuit substrate 130. Therefore, the converter module 100 can be reduced in profile in the present embodiment.

In the case of the converter module 100 in the first embodiment, the semiconductor substrate 120 is connected in the recessed part 118 of the base 112. Thus, the sum of the thicknesses of the semiconductor substrate 120 and the converter 110 on one side can be approximately equal to the thickness of the converter 110 on the other side. On account of this, the thickness of the converter module 100 does not need to be reduced and, therefore, the strength of the converter can be maintained.

Moreover, in the case of the converter module 100 in the first embodiment, the volume of the cavity part 113 is determined by the thickness of the base 112 and the size of the area surrounded by the base 112 and the semiconductor substrate 120 connected in the recessed part 118. This means that thinning the semiconductor substrate 120 does not reduce the volume of the cavity part 113 nor decrease the accuracy in detecting the pressure fluctuations.

As described earlier, in order to improve the detection sensitivity, it is necessary to (A) increase the area size of the diaphragm 111 or (B) increase the volume of the cavity part 113. To achieve (A), the converter 110 needs to be increased in size so as to increase the area size of the diaphragm 111. In the case of the converter module 100 in the first embodiment, since the semiconductor substrate 120 is connected in the recessed part 118 of the base 112, the volume of the cavity part 113 can be increased without changing the size of the semiconductor substrate 120. In fact, when the semiconductor substrate 120 is smaller in size, the volume of the cavity part 113 can be increased more.

The same holds for (B). More specifically, the volume of the cavity part 113 can be increased more when the semiconductor substrate 120 is smaller in size, which means that the detection sensitivity can be improved and that the semiconductor substrate 120 can be reduced in size to the limit. Thus, the number of semiconductor substrates 120 per wafer is increased, which allows the converter module 100 to be manufactured at low cost.

In addition, the size of the semiconductor substrate 120 in view of the detection sensitivity of the converter module 100 does not need to be considered, and this allows greater flexibility in designing the converter module 100.

Therefore, as compared with the conventional converter module, the converter module 100 described as an example in the first embodiment can more easily achieve miniaturization and profile reduction without decreasing the pressure detection sensitivity.

The following describes a method of manufacturing the converter module 100 in the first embodiment, with reference to the drawings.

Firstly, a wafer which is an array having a plurality of converters 110 is prepared. Each of the converters 110 includes the electrode area 114, the diaphragm 111, and the base 112. It should be noted that the converters 110 are formed according to the well-known technique.

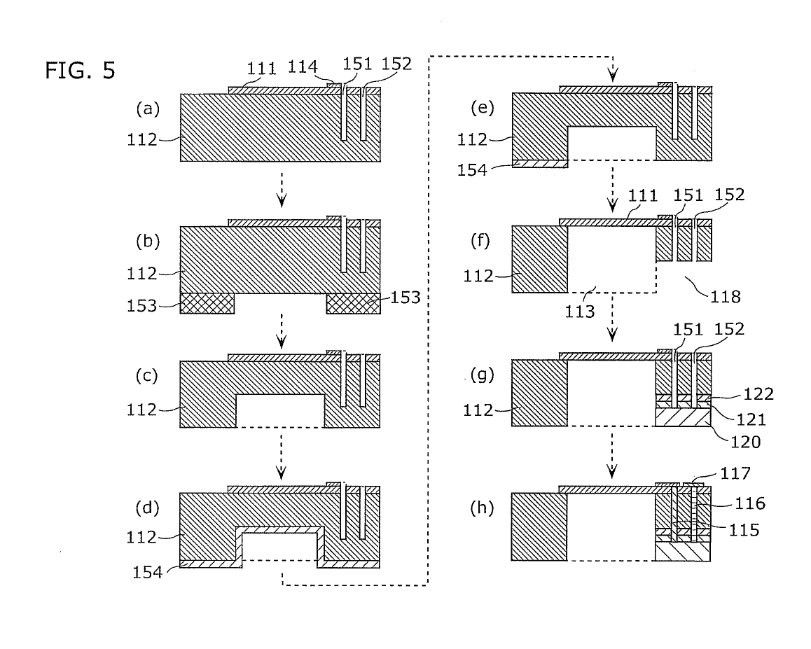

Next, electrode recessed parts 151 and 152 recessed from the front surface of the base 112 in the thickness direction are formed for the penetrating electrodes 115 and 116, respectively. For example, a dry etching process or a wet etching process may be performed using a resist, a SiO₂ film, a metal film, or the like as a mask. Each depth of the electrode recessed parts 151 and 152 is approximately 50 μm to 100 μm. The electrode recessed parts 151 and 152 may completely penetrate the base 112. The penetration manner of the electrode recessed parts 151 and 152 may be determined as appropriate, depending on, for example, diameters of the electrode recessed parts 151 and 152. By this process, a structure shown in (a) of FIG. 5 is formed. Note that FIG. 5 shows only one of the converters 110 formed on the wafer.

After this, the cavity part 113 and the recessed part 118 are formed. The recessed part 118 is formed for connecting the semiconductor substrate 120. The cavity part 113 and the recessed part 118 may be separately formed. However, it is preferable for the cavity part 113 and the recessed part 118 to be formed at one time, in terms of the manufacturing accuracy and the reduced number of processes. Here, suppose that the cavity part 113 and the recessed part 118 are formed at one time. In this case, a material used for a protection film and a deposition method are slightly different between the wet etching process and the dry etching process each of which is performed for etching bulk Si of the base 112.

Thus, the following describes the case where the cavity part 113 and the recessed part 118 are formed at one time by the wet etching process.

Firstly, a SiN film, and more specifically, a first protection film 153, is deposited on the back surface of the base 112 by a chemical vapor deposition (CVD) process or by a reactive sputtering process. Here, a SiO₂ film may be deposited instead of the SiN film.

The SiO₂ film can be deposited by thermal oxidation. In this case, however, Poly-Si of the diaphragm 111 is also oxidized and, as a result, the diaphragm 111 partially becomes SiO₂. Then, there is a possibility that the diaphragm 111 becomes thin and brittle at the completion of the converter module 100. For this reason, it is preferable to perform the CVD process or the reactive sputtering process.

After a photosensitive resist is applied on the SiN film (i.e., the first protection film 153) by a spin coating process, a patterning process is performed on the resist to form an opening for each of the cavity part 113 and the recessed part 118. Following this, using the resist as a mask, a reactive ion etching (RIE) process or the wet etching process is performed to remove the SiN film from the back surface of the base 112 at the area where the cavity part 113 is to be formed. Then, after removing the resist, a structure shown in (b) of FIG. 5 is formed.

Next, using the SiN film (i.e., the first protection film 153) as the protection film, the wet etching process is performed to make the depth of the recessed part 118 approximately 50 μm to 100 μm. In this case, it is preferable to use a tetramethylammonium hydroxide (TMAH) aqueous solution as etchant in the wet etching process. The TMAH aqueous solution does not burden the electrode area 114 and allows an anisotropic etching process to be performed on Si along the crystal orientation with high accuracy. Then, after removing the SiN film using a phosphate solution or the like, a structure shown in (c) of FIG. 5 is formed.

Following this, a SiO₂ film or a SiN film, and more specifically, a second protection film 154, is deposited on the back surface of the base 112 by the CVD process or the reactive sputtering process. As a result, a structure shown in (d) of FIG. 5 is formed. Here, it is preferable for the second protection film 154 to have a sufficient thickness and to be deposited seamlessly so as not to be torn due to the level differences formed in the process shown in (c) of FIG. 5.

Then, after a photosensitive resist is applied on the SiO₂ film (i.e., the second protection film 154) by the spin coating process, the patterning process is performed on the resist to form an opening for each of the cavity part 113 and the recessed part 118. Following this, using the resist as a mask, the RIE process or the wet etching process is performed on the SiO₂ film according to the trace patterns, so as to form the opening for each of the cavity part 113 and the recessed part 118. After removing the resist, a structure shown in (e) of FIG. 5 is formed.

Next, using the SiO₂ film (i.e., the second protection film 154) as the protection film, the wet etching process is performed to etch the bulk Si from the back surface of the base 112 until the back surface of the diaphragm 111 is exposed. As a result, the cavity part 113 and the recessed part 118 are formed. This etching process also penetrates the electrode recessed parts 151 and 152 (50 μm to 100 μm in depth) formed in the base 112. Then, after removing the SiO₂ film using a hydrofluoric acid solution or the like, a structure shown in (f) of FIG. 5 is formed.

In this way, the base 112 is etched from the back surface, so that the cavity part 113 is formed in a first area immediately below the diaphragm 111 and that the recessed part 118 is formed in a second area which is different from the first area.

Next, the semiconductor substrate 120 is boned to the recessed part 118 formed in the base 112. To be more specific, since the etched surface of the recessed part 118 is rough, it is preferable for the semiconductor substrate 120 to be bonded to the recessed part 118 via the insulating paste 122.

Here, the semiconductor substrate 120 is to be fitted in the recessed part 118. On this account, it is preferable for the semiconductor substrate 120 to be previously ground until the resultant thickness is equal to or smaller than a height measured from the etched surface of the recessed part 118 to the back surface of the base 112. To be more specific, it is preferable for the thickness of the base 112 shown in the left side of FIG. 3 to be approximately equal to the sum of the thickness of the base 112 having the recessed part 118 as shown in the right side of FIG. 3 and the thickness of the semiconductor substrate 120.

In addition, the insulating film 121 having an opening for each of the electrode recessed parts 151 and 152 formed in the base 112 is formed on the front surface of the semiconductor substrate 120. It should be noted that only one of the insulating film 121 and the insulating paste 122 may be formed. Accordingly, a structure shown in (g) of FIG. 5 is formed.

Next, the penetrating electrodes 115 and 116 are respectively formed in the electrode recessed parts 151 and 152 formed in the base 112, the insulating paste 122, and the insulating film 121. Note that it is preferable for the penetrating electrodes 115 and 116 to be formed at one time for the purpose of reducing the number of manufacturing processes. More specifically, an insulating film, such as a SiO₂ film, is formed on the front surface of the converter 110 and inside the electrode recessed parts 151 and 152 by the CVD process or an insulating-paste printing-filling process.

Following this, the insulating film formed on the electrode area 114 and the semiconductor substrate 120 at areas corresponding to the bottoms of the electrode recessed parts 151 and 152 is removed by, again, the dry etching process or the wet etching process. Then, a thin metal film is formed on the entire front surface of the converter 110 by a sputtering process or the like. Here, the thin metal film is mainly made of Ti, titanium tungsten (Ti—W), chromium (Cr), or Cu, for example.

Then, after a dry-film pasting process or the application of a photosensitive liquid resist by the spin coating process, the patterning process is performed on the resist for the penetrating electrodes 115 and 116 by exposure and development using a photolithographic technique. It should be noted that the thickness of the resist may be determined according to each thickness of the penetrating electrodes 115 and 116 eventually desired. In general, the thickness is approximately 5 μm to 30 μm. Then, using a metal such as Cu, the penetrating electrodes 115 and 116 are formed by an electrolytic plating process. Here, in order to easily establish an electrical connection between the penetrating electrode 116 and the external electrode 132, the electrode area 117 is formed by the same process as described. After removing the resist, a structure shown in (h) of FIG. 5 is formed.

In the case where the electrode recessed parts 151 and 152 are not filled with the penetrating electrodes 115 and 116, respectively, a filling layer (not illustrated) may be formed in the electrode recessed parts 151 and 152. As a filling material, a resin or a metal may be used.

For example, when a metal is used for filling, metal plating may be performed by the electrolytic plating process or a metal paste may be mainly used by the printing-filling process or a dipping process.

In the case of the electrolytic plating process, it is desirable for the filling to be performed at the same time as when the penetrating electrodes 115 and 116 are formed. In this case, the electrode recessed parts 151 and 152 are completely filled with the filling layers. Suppose here that the filling layers and the penetrating electrodes 115 and 116 are formed separately, for example. In such a case, after the penetrating electrodes 115 and 116 are formed, a mask having an opening for each of the electrode recessed parts 151 and 152 is formed and the filling layer is formed in each of the electrode recessed parts 151 and 152 by the electrolytic plating process.

When a resin material is used for filling, a liquid light-curing or thermo-curing resin may be applied by the spin coating process or a resin paste may be applied by the printing-filling process or the dipping process.

Next, the sound hole 133 is formed in the circuit substrate 130. The sound hole 133 penetrates the circuit substrate 130 in the thickness direction, and is approximately equal in volume to the cavity part 113. It should be noted that the electrical wiring is formed in the circuit substrate 130 at an area where the sound hole 133 is not formed.

Moreover, the external electrode 132 is formed on the electrode area 117 (or, the penetrating electrode 116) by a solder ball placing process using flux, a solder paste printing process, or an electrolytic plating process. After this, via the insulating sheet 131 having an opening corresponding to the sound hole 133, the converter 110 and the semiconductor substrate 120 are temporarily fixed on the circuit substrate 130.

Following this, the insulating sheet 131 and the external electrode 132 are heated under pressure. As a result, the converter 110 and the semiconductor substrate 120 sink toward the circuit substrate 130, and then the circuit substrate 130 and the external electrode 132 can be electrically connected.

After this, the shielding cap 140 is bonded to the converter 110 and the semiconductor substrate 120 via the bonding adhesive 141. Here, the shielding cap 140 is bonded so as to cover each back surface of the converter 110 and the semiconductor substrate 120 to protect the converter module 100 from an external shock or from noise caused by an electromagnetic wave or the like. Without using the bonding adhesive 141, the shielding cap 140 may be boned to each back surface of the converter 110 and the semiconductor substrate 120 by an ultrasonic thermocompression bonding process. After the processes described thus far, the structures as shown in FIG. 1 and FIG. 3 are formed.

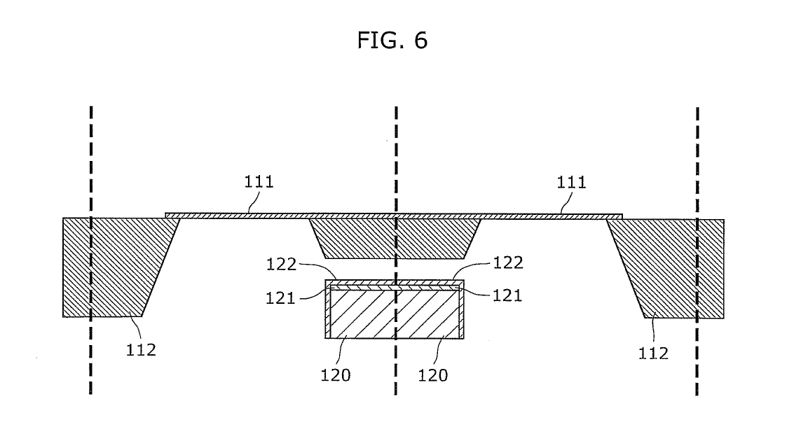

The semiconductor substrate 120 may be formed in the recessed part 118 one at a time. However, for the purpose of reducing the number of manufacturing processes, it is preferable that a plurality of semiconductor substrates 120 be respectively formed in a plurality of recessed parts 118 of the converters 110 at one time, as shown in FIG. 6.

To be more specific, the cavity part 113 and the recessed part 118 are formed in each of the converters 110 formed in the array so that the formed recessed parts 118 of two adjacent converters 110 are adjacent to each other. In the first embodiment, the wafer which is an array having the plurality of converters 110 is used to manufacture a plurality of converter modules 100 at one time. Here, the converters 110 are arranged on the wafer so that areas for the recessed parts 118 of the two adjacent converters 110 are adjacent to each other. With this, two semiconductor substrates 120 are bonded to two converters 110, respectively, at one time as shown in FIG. 6.

In FIG. 5, the inner walls of the base 112 after the etching process (i.e., the side surfaces of the cavity part 113 and the recessed part 118) are illustrated as vertical planes for the sake of simplicity. However, when the wet etching process is performed as described above, the inner walls of the base 112 are sloped as shown in FIG. 3.

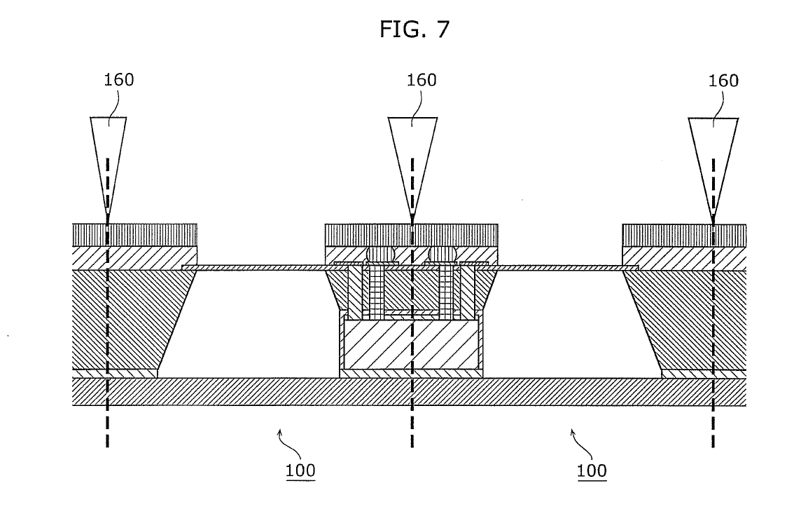

Finally, the wafer is divided into the plurality of converter modules 100 using a cutting member 160, such as a dicing saw or a laser dicer, as shown in FIG. 7.

Accordingly, the converter module 100 in the first embodiment can be manufactured as shown in FIG. 1 to FIG. 3.

As described above, the cavity part 113 and the recessed part 118 are formed by the two etching processes. More specifically, a first etching process is performed on the first area by etching from the back surface of the base 112 to form the cavity part 113 immediately below the diaphragm 111, and then a second etching process is performed on the first area for the cavity part 113 and the second area for the recessed part 118 at one time by etching from the back surface of the base 112. Here, by the first etching process, the back surface of the base 112 is etched so that the base 112 in the first area where the cavity part 113 is to be formed is at least as thick as the semiconductor substrate 120. Moreover, by the second etching process, the back surface of the base 112 is etched at least as deep as the thickness of the semiconductor substrate 120. In this way, the cavity part 113 and the recessed part 118 are formed.

It should be noted that, after the converters 110 and the semiconductor substrates 120 are diced, each of the converters 110 and semiconductor substrates 120 may be picked up to be bonded to the circuit substrate 130.

Moreover, although not illustrated here, each of the external electrode 132 and the insulating sheet 131 may be an anisotropic conductive film. For example, an anisotropic conductive film having an opening for the sound hole 133 is bonded on the circuit substrate 130, and the converter 110 and the semiconductor substrate 120 are temporarily fixed on this anisotropic conductive film. In this case, the anisotropic conductive film previously has a conductive trace pattern at a place where the penetrating electrode 116 and the electrode area 117 are to be bonded. After this, complete bonding is performed by application of pressure and heat.

Furthermore, the insulating paste 122 may be bonded to the base 112 and the semiconductor substrate 120 after the trace patterns for the electrode recessed parts 151 and 152 formed in the base 112 are opened. In addition, it is preferable for the insulating paste 122 not only to bond the main surface of the semiconductor substrate 120 and the back surface of the base 112 where the recessed part 118 is formed, but also to bond the side surface of the semiconductor substrate 120 and the side surface of the base 112 as shown in FIG. 3.

Moreover, the semiconductor substrate 120 may be bonded after the recessed part 118 is formed, and the cavity part 113 may be formed after the penetrating electrodes 115 and 116 are formed. With this, since the surface of the diaphragm 111 is fully supported by the base 112 before the cavity part 113 is formed, process loads on the diaphragm 111 can be reduced. The process loads include stress of when the semiconductor substrate 120 is bonded, plating stress of when the penetrating electrodes 115 and 116 are formed, and wafer handling.

Furthermore, the cavity part 113 and the recessed part 118 may be formed by the dry etching process. The following describes the case where the cavity part 113 and the recessed part 118 are formed by the dry etching process.

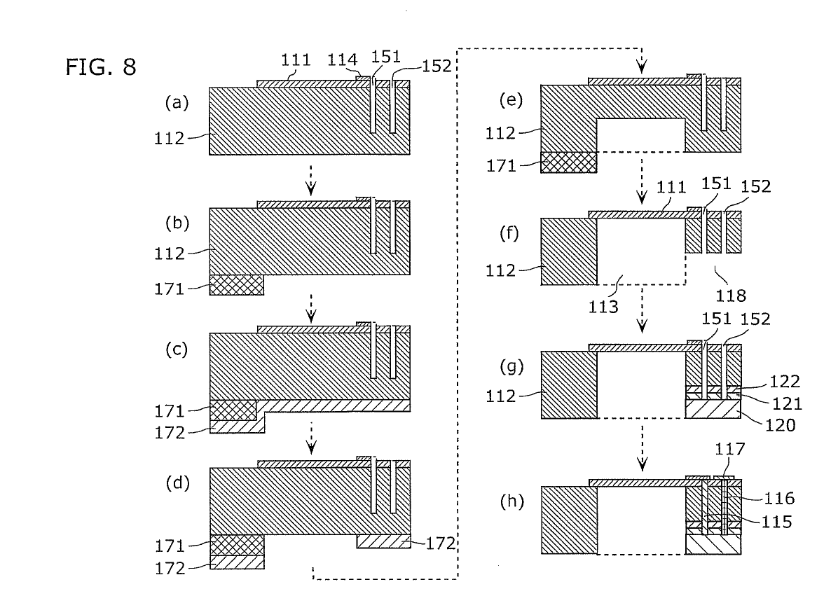

Firstly, as in the case shown in (a) of FIG. 5, the electrode recessed parts 151 and 152 are formed in the converter 110 including the electrode area 114, the diaphragm 111, and the base 112. As a result, a structure shown in (a) of FIG. 8 is formed.

Next, a first protection film 171 which a resist, a SiN film, a SiO₂ film, or a thin metal film is deposited on the back surface of the base 112. After this, the patterning process is performed on the first protection film 171 for openings of the cavity part 113 and the recessed part 118. The openings may be formed by either the wet etching process or the dry etching process (RIE process). As a result, a structure shown in (b) of FIG. 8 is formed.

After this, a second protection film 172 is deposited. The second protection film is a resist, a SiN film, a SiO₂ film, or a thin metal film having etching resistance different from the etching resistance of the first protection film 171 deposited in the previous process. As a result, a structure shown in (c) of FIG. 8 is formed. Then, as in the case above, the wet etching process is performed to form the opening of the cavity part 113 according to the trace pattern. Thus, a structure shown in (d) of FIG. 8 is formed.

Next, the dry etching process (RIE process) is performed on the back surface of the base 112 to make the depth of the recessed part 118 approximately 50 μm to 100 μm. For example, the base 112 is etched by the dry etching process using fluorinated gas. Following this, the second protection film 172 formed on the back surface of the base 112 is removed. As a result, a structure shown in (e) of FIG. 8 is formed.

Finally, the dry etching process is performed to etch the back surface of the base 112 until the back surface of the diaphragm 111 is exposed. As a result, the cavity part 113 and the recessed part 118 are formed. This etching process also penetrates the electrode recessed parts 151 and 152 (50 μm to 100 μm in depth) formed in the base 112. Then, after removing the first protection film 171, a structure shown in (f) of FIG. 8 is formed.

The subsequent processes are the same as those performed in the case of the wet etching process, as shown in (g) and (h) of FIG. 8.

As described thus far, the cavity part 113 and the recessed part 118 can be formed by the dry etching process. It should be noted that since each of the first protection film 171 and the second protection film 172 can be deposited approximately evenly in the example shown in FIG. 8, the base 112 can be protected more solidly.

Here, it is preferable for the first protection film 171 and the second protection film 172 to be made of different materials. Suppose that the first protection film 171 is a SiN film and that the second protection film 172 is a SiO₂ film. In this case, etchants used in the wet etching process are different between the SiN film and the SiO₂ film. For example, a phosphate solution is used in the wet etching process performed on the SiN film whereas a hydrofluoric acid solution is used in the wet etching process performed on the SiO₂ film. This means that when the SiO₂ film is etched, the SiN film having deposited earlier is hardly etched. On this account, it is preferable to perform the wet etching process for etching the protection films.

A method of depositing the protection films is not limited to the method described above. For example, as shown in FIG. 8, the two protection films are firstly deposited and, after this, the base 112 may be etched by the wet etching process.

### Second Embodiment

In a converter module in the second embodiment, a through area penetrating from a front surface of a base to a back surface of the base is formed, and a semiconductor substrate is formed in this through area.

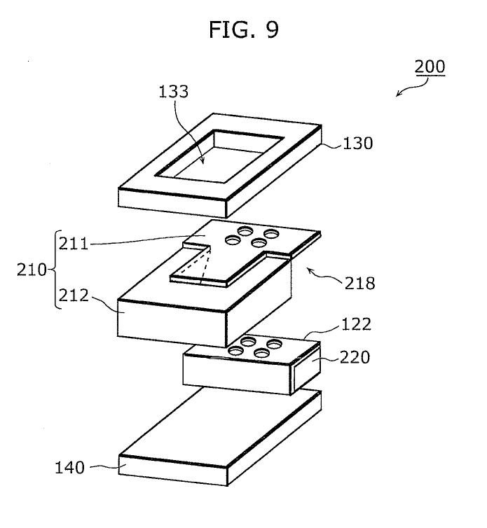

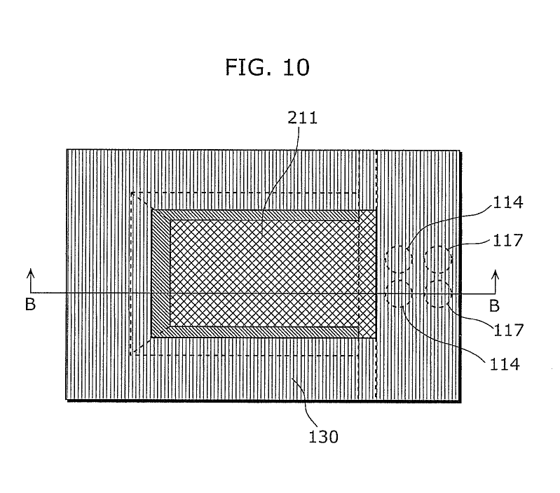

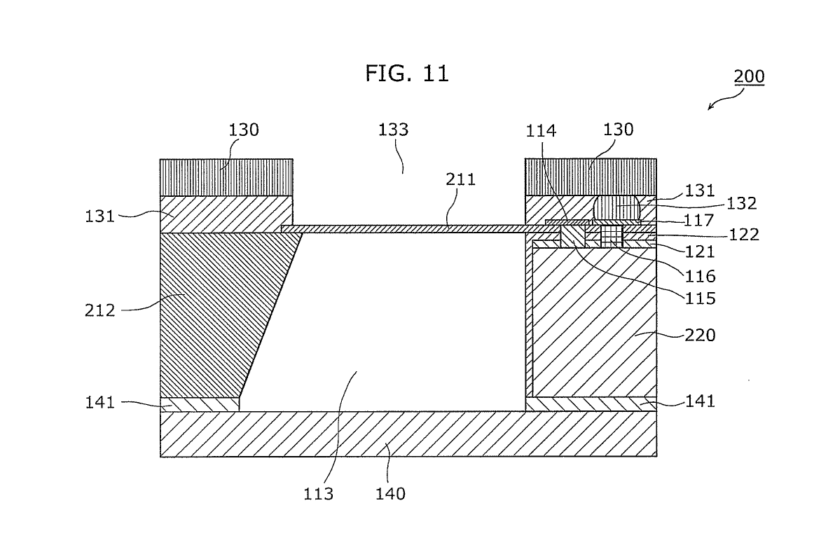

The following is a description of the converter module in the second embodiment. FIG. 9 is a perspective view of a converter module 200 in the second embodiment. FIG. 10 is a plan view of the converter module 200 in the second embodiment. FIG. 11 is a cross-sectional view of the converter module 200 in the second embodiment taken along a line B-B in FIG. 10.

As shown in FIG. 9 to FIG. 11, a base 212 included in the converter module 200 is different in shape from the base 112 included in the converter module 100 shown in FIG. 1 to FIG. 3 in the first embodiment. In the present embodiment, components identical to those in the first embodiment are assigned the same numerals used in the first embodiment and, therefore, the detailed explanations of these components are omitted and different components are mainly explained.

As shown in FIG. 11, the base 212 includes a through area 218 (corresponding to the recessed part 118 in the first embodiment) which penetrates from a front surface of the base 212 to a back surface of the base 212, in the converter module 200 of the second embodiment. Here, the front surface and the back surface of the base 212 may be referred to as a first main surface and a second main surface, respectively. In this through area 218, a semiconductor substrate 220 is formed. The back surface of the base 212 and a back surface of the semiconductor substrate 220 are in one plane. This means that the thickness of the base 212 is approximately equal to a sum of the thicknesses of the semiconductor substrate 220, the insulating film 121, and the insulating paste 122.

Since the base 212 is not formed on the semiconductor substrate 220, each of the penetrating electrodes 115 and 116 penetrates only a diaphragm 211, the insulating film 121, and the insulating paste 122. In this way, the penetrating electrodes 115 and 116 can be shortened. Therefore, the converter module 200 can reduce parasitic resistance caused by the electrode part more than the converter module 100 in the first embodiment, in addition to the advantageous effect described in the first embodiment.

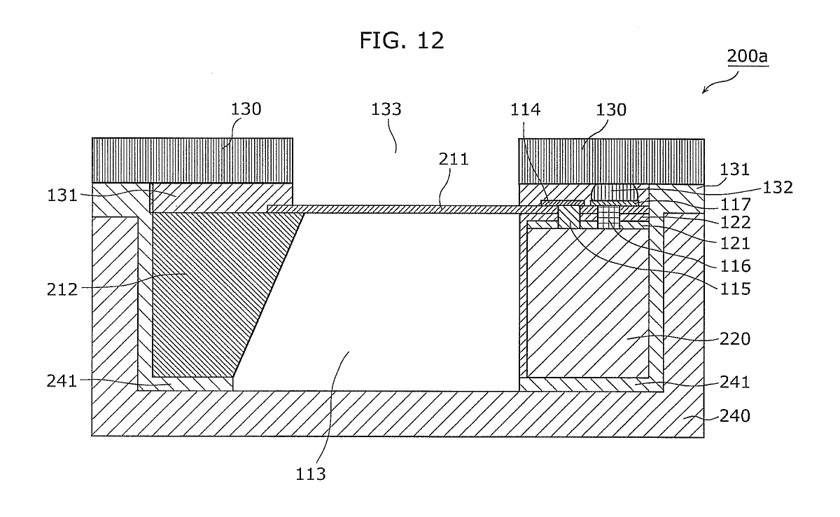

Note that the shielding cap 140 may cover not only a back surface of the converter module 200 but also side surfaces of the converter module 200. FIG. 12 is a cross-sectional view of a configuration of a converter module 200a, as a modification of the converter module 200 in the second embodiment. As shown in FIG. 12, a shielding cap 240 of the converter module 200a covers side surfaces of a converter 210 and the semiconductor substrate 220 as well, via a bonding adhesive 241.

With this configuration, the converter module 200a can be more protected from an external shock or from noise caused by an electromagnetic wave or the like. Here, the way of applying the bonding adhesive 241 can be selected as appropriate. More specifically, the bonding adhesive 241 may be fully applied to a surface where the converter 210 and the shielding cap 240 meet or may be applied only to a surface where the circuit substrate 130 and the shielding cap 240 meet.

Next, points of difference between a method of manufacturing the converter module 200 in the second embodiment and the method of manufacturing the converter module 100 in the first embodiment are explained.

As mentioned, the base 212 included in the converter module 200 is different in shape from the base 112 included in the converter module 100 in the first embodiment. To be more specific, the area for forming the semiconductor substrate 220 penetrates the base 212 in the converter module 200. That is, the through area 218 can be formed by the same process performed for forming the cavity part 113.

Thus, as shown in (b) of FIG. 8, a protection film which a resist, a SiN film, a SiO₂ film, or a thin metal film is deposited on the back surface of the base 212. After this, the patterning process is performed on the protection film for openings of the cavity part 113 and the through area 218 (corresponding to the recessed part 118 in the first embodiment). Then, the wet etching process or the dry etching process, for example, is performed to penetrate the base 212 from the back surface to the front surface.

With this, the two-step process including lithography and etching to form the cavity part 113 and the through area 218 is not necessary. This can reduce the number of manufacturing processes and, thus, the converter module 200 can be manufactured at low cost.

### Third Embodiment

In a converter module in the third embodiment, a shielding cap having a sound hole is arranged on a front surface of a base or above a diaphragm, and a circuit substrate for transmitting an electric signal to an external source is arranged on a back surface of the base.

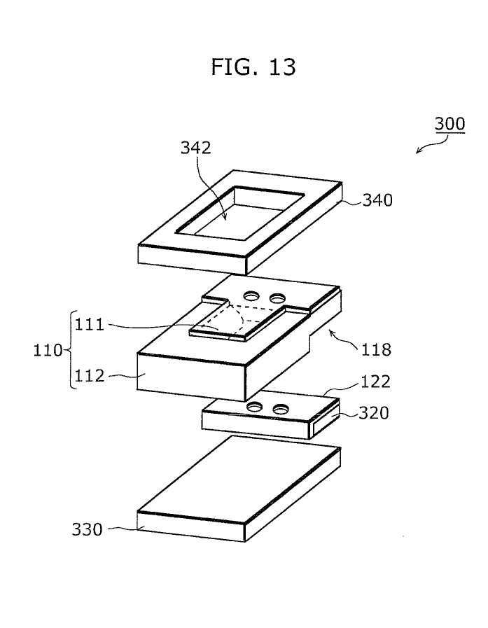

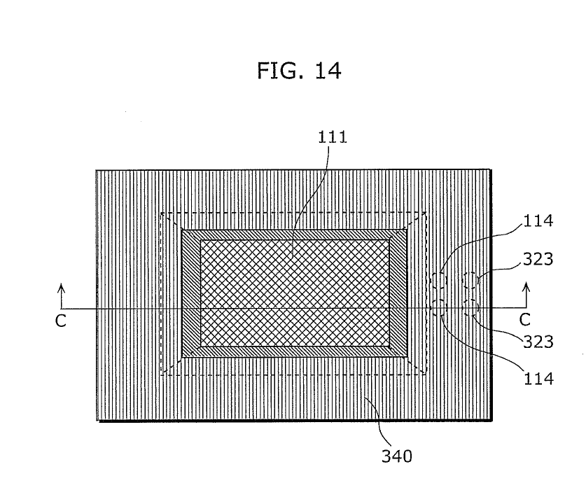

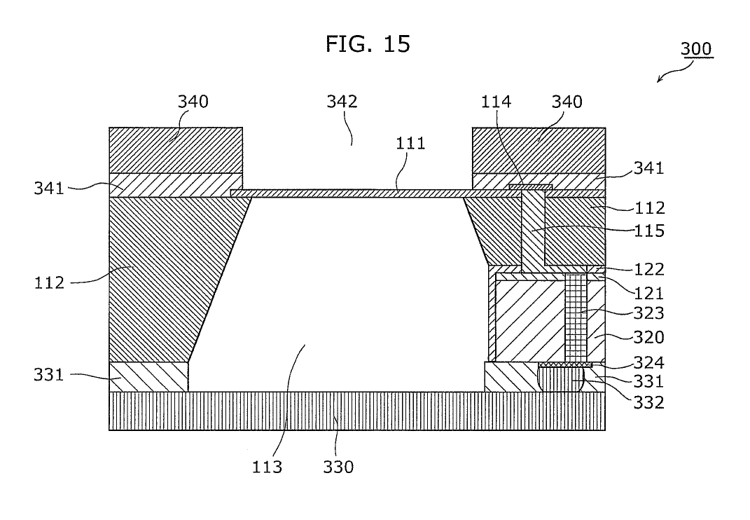

The following is a description of the converter module in the third embodiment. FIG. 13 is a perspective view of a converter module 300 in the third embodiment. FIG. 14 is a plan view of the converter module 300 in the third embodiment. FIG. 15 is a cross-sectional view of the converter module 300 in the third embodiment taken along a line C-C in FIG. 14.

As shown in FIG. 13 to FIG. 15, the converter module 300 is different from the converter module 100 in the first embodiment in that a shielding cap 340 is arranged on the front surface of the base 112 and a circuit substrate 330 is arranged on the back surface of the base 112. In the present embodiment, components identical to those in the first embodiment are assigned the same numerals used in the first embodiment and, therefore, the detailed explanations of these components are omitted and different components are mainly explained.

As shown in FIG. 13 to FIG. 15, the shielding cap 340 is formed on the front surface of the converter 110 and above the diaphragm 111. To be more specific, the shielding cap 340 is bonded to the front surface of the base 112, the diaphragm 111, and the electrode area 114 via a bonding adhesive 341.

The shielding cap 340 is an example of a protection film having a sound hole 342 penetrating the protection film in the thickness direction. Here, the shielding cap 340 is formed above the diaphragm 111 so that the opening of the cavity part 113 is located immediately below the sound hole 342.

The circuit substrate 330 is arranged on the back surface of the base 112. More specifically, the circuit substrate 330 is bonded to the back surface of the base 112 and to a back surface of a semiconductor substrate 320 via an insulating sheet 331. Moreover, in the circuit substrate 330, electrical wiring is formed to, for example, extract the electric signal processed by the semiconductor substrate 320.

Moreover, a penetrating electrode 323 is formed inside a through hole penetrating the semiconductor substrate 320 in the thickness direction. The penetrating electrode 323 is electrically connected to the penetrating electrode 115 and extends to a part of the back surface of the semiconductor substrate 320. The penetrating electrode 323 is an example of a third penetrating electrode which penetrates the semiconductor substrate 320 in the thickness direction and which electrically connects the semiconductor substrate 320 and the electrical wiring formed in the circuit substrate 330. To be more specific, the penetrating electrode 323 is electrically connected to the electrical wiring formed in the circuit substrate 330 in order to transmit, to an external source, the electric signal processed by the semiconductor substrate 320. The penetrating electrode 323 is made of a metal, such as Ti or Cu.

An external electrode 332 is formed in the insulating sheet 331 to electrically connect the penetrating electrode 323 and the circuit substrate 330. Here, the external electrode 332 is made of, for example, a lead-free solder material which is a Sn—Ag—Cu alloy.

Since the cavity part 113 is formed in an area surrounded by the circuit substrate 330, the base 112, and the semiconductor substrate 320 connected in the recessed part 118, the converter module 300 in the third embodiment can achieve the advantageous effect described in the first embodiment.

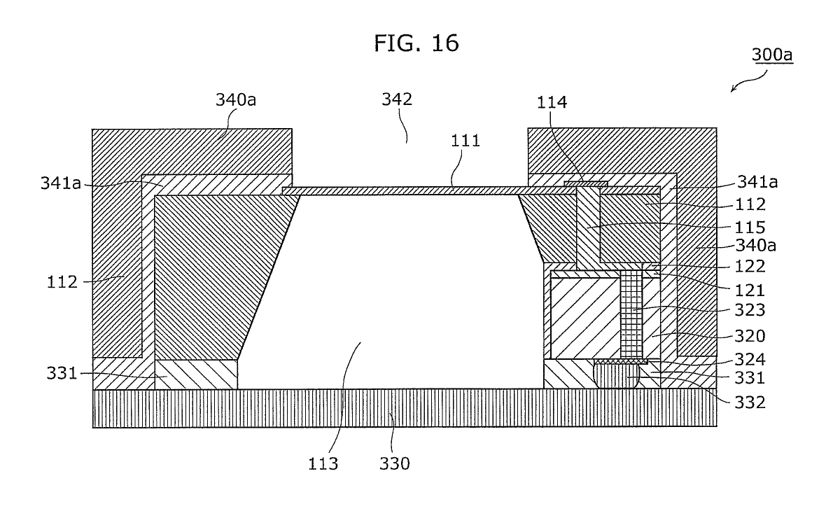

Note that the shielding cap 340 may cover not only a front surface of the converter module 300 but also side surfaces of the converter module 300. FIG. 16 is a cross-sectional view of a configuration of a converter module 300a, as a modification of the converter module 300 in the third embodiment. As shown in FIG. 16, a shielding cap 340a of the converter module 300a covers side surfaces of the converter 110 and the semiconductor substrate 320 as well, via a bonding adhesive 341a. In this way, the shielding cap 340a, which is an example of a protection layer, protects the back surface and side surfaces of the base 112.

With this configuration, the converter module 300a can be more protected from an external shock or from noise caused by an electromagnetic wave or the like. Here, the way of applying the bonding adhesive 341a can be selected as appropriate. More specifically, the bonding adhesive 341a may be fully applied to a surface where the converter 110 and the shielding cap 340a meet or may be applied only to a surface where the circuit substrate 330 and the shielding cap 340a meet.

Next, points of difference between a method of manufacturing the converter module 300 in the third embodiment and the method of manufacturing the converter module 100 in the first embodiment are explained.

As mentioned above, the converter module 300 is different from the converter module 100 in the first embodiment in that the shielding cap 340 is arranged on the front surface of the base 112 and the circuit substrate 330 is arranged on the back surface of the base 112. Moreover, since the circuit substrate 330 is located at a different position from the position of the circuit substrate 130 in the first embodiment, the penetrating electrode 323, instead of the penetrating electrode 116, is formed in the semiconductor substrate 320. On account of this, a process of forming the penetrating electrode and a process of bonding the shielding cap and the circuit substrate are different between the manufacturing methods in the first and third embodiments. The detailed explanation is given as follows.

In the process of forming the electrode recessed parts 151 and 152 as shown in (a) of FIG. 8 in the first embodiment, only the electrode recessed part 151 for forming the penetrating electrode 115 is formed in the base 112 in the present embodiment. Then, after the semiconductor substrate 320 is bonded to the base 112, the through hole penetrating the semiconductor substrate 320 in the thickness direction is formed and the penetrating electrode 323 is formed in the formed through hole.

More specifically, an electrode area 324 is firstly formed on the back surface of the semiconductor substrate 320. Next, the patterning process is performed on a protection film which a resist, a SiN film, a SiO₂ film, or a thin metal film formed on the back surface of the semiconductor substrate 320, so as to penetrate immediately below the electrode area 324. After this, the dry etching process or the wet etching process, for example, is performed. As a result, the through hole is formed in the semiconductor substrate 320. Following this, the penetrating electrode 323 is formed by the same process performed for forming the penetrating electrode 115.

Next, the sound hole 342 is formed in the shielding cap 340, and the shielding cap 340 is bonded to the base 112 and the diaphragm 111 via the bonding adhesive 341. Moreover, the circuit substrate 330 is bonded to the back surfaces of the base 112 and the semiconductor substrate 320 via the insulating sheet 331. Here, the external electrode 332 is formed in the insulating sheet 331 as in the first embodiment. Although it is desirable for the insulating sheet 331 to have an opening to increase the volume of the cavity part 113, the opening of the insulating sheet 331 does not necessarily correspond to the trace pattern of the cavity part 113.

The circuit substrate 330 of the converter module 300 in the third embodiment includes no hole, and this allows greater flexibility in designing the converter module 300. To be more specific, in the first and second embodiments, the electrical wiring formed in the circuit substrate 130 needs to be formed so as not to be cut due to the sound hole 133. However, this concern does not need to be considered in the case of the converter module 300 in the third embodiment.

### Fourth Embodiment

In a converter module in the fourth embodiment, a through area penetrating from a front surface of a base to a back surface of the base is formed, and a semiconductor substrate is formed in this through area. As in the case of the third embodiment, a shielding cap having a sound hole is arranged on the front surface of the base or above a diaphragm, and a circuit substrate for transmitting an electric signal to an external source is provided on the back surface of the base.

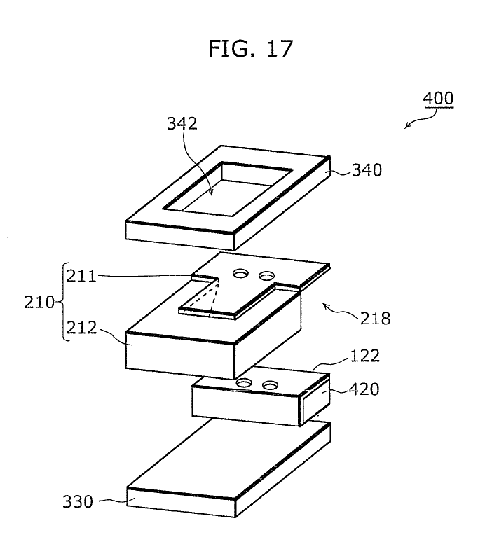

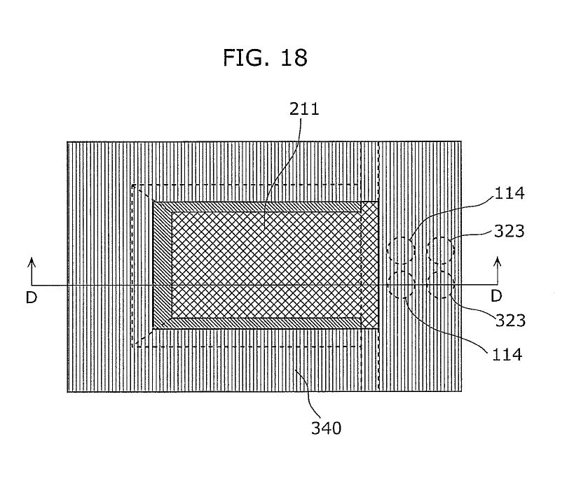

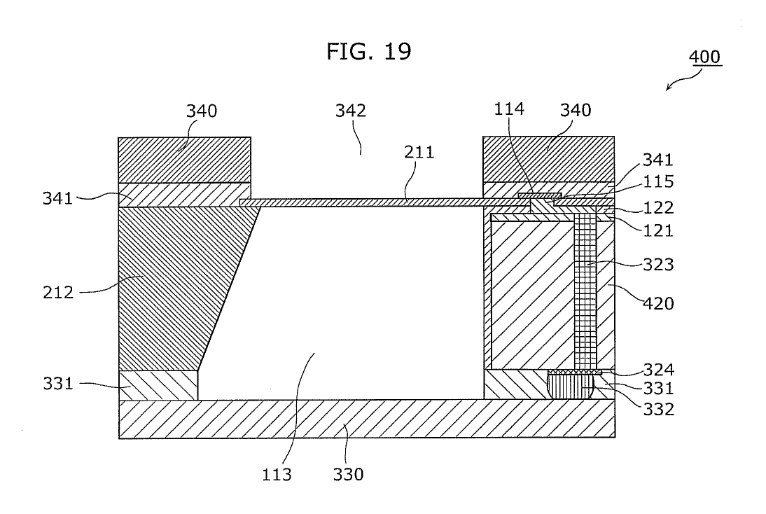

The following is a description of the converter module in the fourth embodiment. FIG. 17 is a perspective view of a converter module 400 in the fourth embodiment. FIG. 18 is a plan view of the converter module 400 in the fourth embodiment. FIG. 19 is a cross-sectional view of the converter module 400 in the fourth embodiment taken along a line D-D in FIG. 18.

As shown in FIG. 17 to FIG. 19, a base 212 included in the converter module 400 is different in shape from the base 112 included in the converter module 300 shown in FIG. 13 to FIG. 15 in the third embodiment. In the present embodiment, components identical to those in the third embodiment are assigned the same numerals used in the third embodiment and, therefore, the detailed explanations of these components are omitted and different components are mainly explained.

As shown in FIG. 19, the base 212 includes a through area 218 (corresponding to the recessed part 118 in the third embodiment) which penetrates from a front surface of the base 212 to a back surface of the base 212, in the converter module 400 of the fourth embodiment. Here, the front surface and the back surface of the base 212 may be referred to as a first main surface and a second main surface, respectively. In this through area 218, a semiconductor substrate 420 is formed. The back surface of the base 212 and a back surface of the semiconductor substrate 420 are in one plane. This means that the thickness of the base 212 is approximately equal to a sum of the thicknesses of the semiconductor substrate 420, the insulating film 121, and the insulating paste 122.

Since the base 212 is not formed on the semiconductor substrate 420, the penetrating electrode 115 penetrates only a diaphragm 211, the insulating film 121, and the insulating paste 122. In this way, the penetrating electrode 115 can be shortened. Therefore, the converter module 400 can reduce parasitic resistance caused by the penetrating electrode 115 more than the converter module 300 in the third embodiment, in addition to the advantageous effect described in the third embodiment.

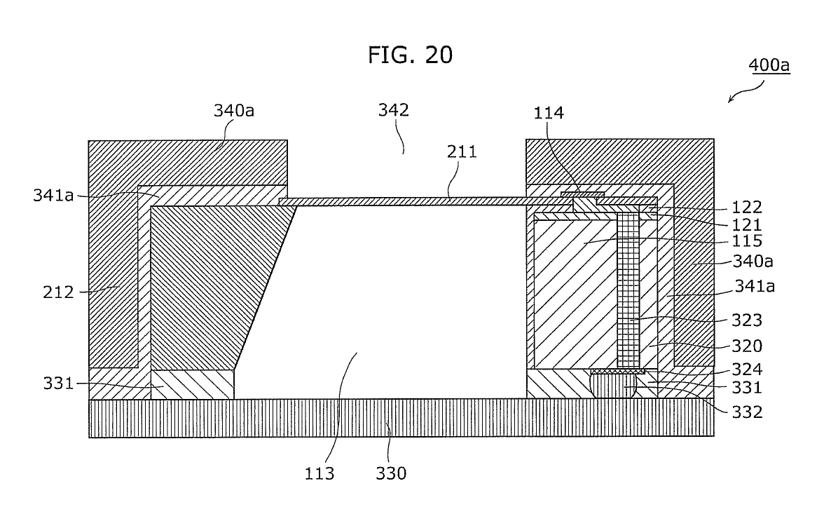

Note that the shielding cap 340 may cover not only a back surface of the converter module 400 but also side surfaces of the converter module 400. FIG. 20 is a cross-sectional view of a configuration of a converter module 400a, as a modification of the converter module 400 in the fourth embodiment. As shown in FIG. 20, a shielding cap 340a of the converter module 400a covers side surfaces of a converter 210 and the semiconductor substrate 420 as well, via a bonding adhesive 341a.

With this configuration, the converter module 400a can be more protected from an external shock or from noise caused by an electromagnetic wave or the like. Here, the way of applying the bonding adhesive 341a can be selected as appropriate. More specifically, the bonding adhesive 341a may be fully applied to a surface where the converter 210 and the shielding cap 340a meet or may be applied only to a surface where the circuit substrate 330 and the shielding cap 340a meet.

Next, points of difference between a method of manufacturing the converter module 400 in the fourth embodiment and the method of manufacturing the converter module 300 in the third embodiment are explained.

As mentioned, the base 212 included in the converter module 400 is different in shape from the base 112 included in the converter module 300 in the third embodiment. To be more specific, the area for forming the semiconductor substrate 420 penetrates the base 212 in the converter module 400. That is, the through area 218 can be formed by the same process performed for forming the cavity part 113.

Thus, as shown in (b) of FIG. 8, a protection film which a resist, a SiN film, a SiO₂ film, or a thin metal film is deposited on the back surface of the base 212. After this, the patterning process is performed on the protection film for openings of the cavity part 113 and the through area 218 (corresponding to the recessed part 118 in the first or third embodiment). Then, the wet etching process or the dry etching process, for example, is performed to penetrate the base 212 from the back surface to the front surface.

With this, the two-step process including lithography and etching to form the cavity part 113 and the through area 218 is not necessary. This can reduce the number of manufacturing processes and, thus, the converter module 400 can be manufactured at low cost.

Although the converter module and the method of manufacturing the same according to the present invention have been fully described by way of embodiments, the present invention is not limited to these embodiments. It is to be noted that various changes and modifications will be apparent to those skilled in the art. Therefore, unless such changes and modifications depart from the scope of the present invention, they should be construed as being included therein.

For example, since the semiconductor substrate in each of the above embodiments is formed in the recessed part or the through area formed by etching from the back surface of the base, the back surface of the semiconductor substrate and the back surface of the base are in one plane. However, the semiconductor substrate may be arranged in any place as long as the semiconductor substrate is formed as a part of the base. The semiconductor substrate may be exposed on the surface of the base or may be formed inside the base, for instance. In such a case, however, it is preferable that the arrangement of the semiconductor substrate does not result in that the converter is thicker than the base.

Moreover, in each of the above embodiments, the cavity part and the recessed part are formed by the etching process. However, a converter previously having the cavity part may be used and only the recessed part may be formed.

The converter module according to the present invention can be used as a sound pressure sensor, a pressure sensor, or a flow sensor. When the converter module is used as a flow sensor, a path for gas is formed above the circuit substrate having the sound hole or above the shielding cap, so that the gas is guided into the sound hole. Then, the diaphragm vibrates in response to the guided gas, and the converter module according to the present invention can be used as the flow sensor detecting this vibration.

### INDUSTRIAL APPLICABILITY

The converter module according to the present invention is capable of easily achieving miniaturization and profile reduction without decreasing the pressure detection sensitivity, and is suitable especially for various kinds of sensors, such as a sound pressure sensor, a pressure sensor, and a flow sensor.

What is claimed is:

1. A converter module comprising:
a converter which converts vibration of a diaphragm into an electric signal; and
a semiconductor substrate which processes the electric signal obtained as a result of the conversion performed by said converter,
wherein said converter includes:
a base including a cavity part having an opening in a first main surface of said base; and
said diaphragm which is arranged on said first main surface to cover the opening of said cavity part and converts the vibration into the electric signal, and
said semiconductor substrate is formed as a part of said base.

2. The converter module according to claim 1,
wherein a part of a side surface of said semiconductor substrate faces said cavity part.

3. The converter module according to claim 1,
wherein a part of a side surface of said base and a part of a side surface of said semiconductor substrate are in one plane.

4. The converter module according to claim 1,
wherein said base includes a recessed part having an opening in a second main surface of said base, the second main surface being opposite to said first main surface, and
said semiconductor substrate is formed in said recessed part.

5. The converter module according to claim 4,
wherein said second main surface of said base and a main surface of said semiconductor substrate are in one plane.

6. The converter module according to claim 1,
wherein said base includes a through area penetrating from said first main surface to a second main surface opposite to said first main surface, and
said semiconductor substrate is formed in said through area.

7. The converter module according to claim 6,
wherein said second main surface of said base and a main surface of said semiconductor substrate are in one plane.

8. The converter module according to claim 1, further comprising:
a first insulating layer formed between said semiconductor substrate and said base; and
a first penetrating electrode penetrating each of said base and said first insulating layer in a thickness direction and electrically connecting said diaphragm and said semiconductor substrate.

9. The converter module according to claim 1, further comprising
a protection layer including a hole penetrating in a thickness direction,
wherein said protection layer is arranged above said diaphragm so that the opening of said cavity part is located immediately below said hole.

10. The converter module according to claim 9,
wherein said protection layer includes electrical wiring for transmitting, to an external source, the electric signal processed by said semiconductor substrate, and
said converter module further comprises
a second penetrating electrode penetrating said base in a thickness direction and electrically connecting said semiconductor substrate and said electrical wiring.

11. The converter module according to claim 10, further comprising:
a second insulating layer formed between said first main surface of said base or said diaphragm and said protection layer; and
an external electrode penetrating said second insulating layer and electrically connecting said second penetrating electrode and said electrical wiring.

12. The converter module according to claim 10, further comprising
a shielding cap protecting a second main surface of said base and a side surface of said base, said second main surface being opposite to said first main surface.

13. The converter module according to claim 9, further comprising:
a circuit substrate which includes electrical wiring for transmitting, to an external source, the electric signal processed by said semiconductor substrate and is formed on a second main surface of said base, said second main surface being opposite to said first main surface; and
a third penetrating electrode penetrating said semiconductor substrate in a thickness direction and electrically connecting said semiconductor substrate and said electrical wiring.

14. The converter module according to claim 13,
wherein said protection layer is a shielding cap further protecting said base by covering a side surface of said base.

15. A method of manufacturing a converter module including a converter which converts vibration of a diaphragm into an electric signal and a semiconductor substrate which processes the electric signal obtained as a result of the conversion performed by the converter,
the converter including:
a base; and
the diaphragm which is arranged on a first main surface of the base and converts the vibration into the electric signal, and
said method comprising:
etching the base from a second main surface opposite to the first main surface to form a cavity part in an first area immediately below the diaphragm and a recessed part in a second area different from the first area, the cavity part penetrating the base in a thickness direction; and
bonding the semiconductor substrate to the recessed part formed in said etching.

16. The method of manufacturing a converter module according to claim 15,
wherein, in said etching, the cavity part and the recessed part are formed in each of a plurality of converters formed in an array so that the formed recessed parts of two adjacent converters are adjacent to each other, each of the converters including the base and the diaphragm,
in said bonding, two semiconductor substrates are respectively bonded, at one time, to the adjacent recessed parts formed in said etching, and
said method further comprises
dicing the array so that the plurality of converters are individually separated.

17. The method of manufacturing a converter module according to claim 15,
wherein said etching includes:
performing a first etching on the first area immediately below the diaphragm by etching from the second main surface of the base; and
performing a second etching on the first area etched in said performing a first etching and on the second area at one time by etching from the second main surface of the base, to form the cavity part in the first area and the recessed part in the second area.

18. The method of manufacturing a converter module according to claim 17,
wherein, in said performing a first etching, the first area is etched so that the base immediately below the diaphragm is at least as thick as the semiconductor substrate, and
in said performing a second etching, the first area etched in said performing a first etching and the second area are etched at least as deep as a thickness of the semiconductor substrate.

19. The method of manufacturing a converter module according to claim 15,
wherein, in said etching, the cavity part and the recessed part are formed at one time so that the recessed part penetrates the base in the thickness direction.
